(19) United States
(12) Patent Application Publication
(10) Pub. No.: US 2006/0261413 A1
(43) Pub. Date: Nov. 23, 2006

(54) Semiconductor device and photoelectric conversion device and scanner using the same

(76) Inventors: Nobuyuki Yamada, Kyoto-shi (JP); Toshimitsu Tamagawa, Kyoto-shi (JP)

Correspondence Address: FISH & RICHARDSON P.C., P.O. BOX 1022, MINNEAPOLIS, MN, 55440-1022, US

(21) Appl. No.: 11/433,704

(22) Filed: May 11, 2006

(30) Foreign Application Priority Data
May 13, 2005 (JP) 2005-141217 (P)

(51) Int. Cl. H01L 23/62

(52) U.S. Cl. 257/355; 257/461; 257/E31.111

(57) ABSTRACT

A semiconductor device includes a photoelectric conversion element outputting an electric signal in accordance with an externally input optical signal, an internal circuit processing the electric signal, a signal terminal inputting or outputting a signal to the internal circuit, a first voltage terminal supplying a first voltage to the internal circuit, and a second voltage terminal supplying a second voltage lower than the first voltage to the internal circuit. The semiconductor device further includes a first protection element connected in an electrically reverse direction between the signal terminal and the first voltage and having at least one PN junction and a second protection element connected in an electrically reverse direction between the first voltage and the second voltage and having at least one PN junction, so that immunity to electrostatic noise can be improved and electrostatic breakdown and malfunction of the photoelectric conversion element can be suppressed.

### BACKGROUND OF THE INVENTION

1. Field of the Invention

The present invention relates to a semiconductor device converting an optical signal to an electric signal, and to a semiconductor device configured to improve immunity to electrostatic breakdown and to prevent malfunction caused by electrostatic noise by arranging a new protection element at a prescribed position as well as to a photoelectric conversion device using the semiconductor device or a scanner using the photoelectric conversion device.

2. Description of the Background Art

In a scanner reading various image data, for example as shown in FIG. 7, a document is fixed on a glass surface 54 and irradiated with light from below, an image sensor portion 51 reading an image is moved, the light reflected from the document is converted to an electric signal, and the data is transferred to information equipment such as a computer. A flatbed scanner 500 includes image sensor portion 51 reading the image, a control unit 52 processing a signal input from image sensor portion 51 and outputting the same to the computer or the like, a flexible cable 53 connecting control unit 52 and image sensor portion 51 to each other, glass portion 54 provided above image sensor portion 51, and a housing 55. As shown in FIG. 8, in the image sensor portion, a plurality of semiconductor chips 600a, 600b, . . . , 600n are arranged in its longitudinal direction.

For example, if a person touches the scanner or the surroundings of the scanner during reading of the image, electrostatic discharge from the human body occurs. Application of excessive pulsed electrostatic noise to the semiconductor chip may result in breakdown of an internal circuit of the semiconductor chip.

Accordingly, conventionally in such a semiconductor chip as well, for example as shown in Japanese Patent Laying-Open No. 11-054701, a diode connected in an electrically reverse direction is inserted as a protection element between a line through which an electric signal input from the outside of a semiconductor device 600 is transmitted and a power supply line and between the line through which the electric signal input from the outside of semiconductor device 600 is transmitted and a reference voltage line, so that breakdown of an internal circuit 69 is prevented even if pulsed electrostatic noise having a prescribed voltage or greater or a prescribed voltage or lower is applied.

FIGS. 9A and 9B show a configuration of semiconductor device 600 implementing a conventional image sensor portion. Semiconductor device 600 includes a first electrostatic protection circuit 60, an input terminal 61 receiving an electric signal, a first voltage terminal 62 receiving a power supply voltage Vcc, a second voltage terminal 63 receiving a reference voltage Vss, a first resistor 64 having one end connected to input terminal 61, a first diode 65 having an anode connected to the other end of first resistor 64 and a cathode connected to first voltage terminal 62, a second diode 66 having a cathode connected to the other end of first resistor 64 and an anode connected to second voltage terminal 63, and a second resistor 67 having one end connected to a point of connection of first resistor 64, the anode of first protection element 65 and the cathode of second protection element 66.

In addition, the semiconductor device includes a photodiode 70 converting input light to an electric signal, internal circuit 69 receiving an electric signal from input terminal 61 through first electrostatic protection circuit 60 and a first buffer 68 and processing the input signal and outputting an electric signal, and a second electrostatic protection circuit 80 constituted of a third diode 81 having an anode side connected to an output of internal circuit 69 and a cathode side connected to first voltage terminal 62, a fourth diode 82 having a cathode side connected to the output of internal circuit 69 and an anode side connected to second voltage terminal 63, and an output terminal 83 connected to a point of connection of the anode side of third diode 81, the cathode side of fourth diode 82 and the output of internal circuit 69.

An example in which a voltage not smaller than a prescribed abnormal voltage (Vcc+Vf1 (V), hereinafter referred to as a first positive overvoltage) is applied to input terminal 61 will be described with reference to an equivalent circuit diagram in FIG. 10A. Here, a forward voltage of first diode 65 is denoted as Vf1, and a forward voltage of second diode 66 is denoted as Vf2. Even if the voltage not smaller than the first positive overvoltage is applied to input terminal 61, the current that flows through first diode 65 is in the forward direction and the current flows through a path shown with I+. Therefore, the voltage not smaller than the first positive overvoltage is not applied to internal circuit 69.

An example in which a voltage not larger than a prescribed abnormal voltage (Vss−Vf2 (V), hereinafter referred to as a first negative overvoltage) is applied to the input terminal will next be described with reference to an equivalent circuit diagram in FIG. 10B. If the voltage not larger than the first negative overvoltage is applied to input terminal 61, the current that flows through second diode 66 is in the forward direction and the current flows through a path shown with I−. Therefore, the voltage not larger than the first negative overvoltage is not applied to internal circuit 69.

Here, diodes 65, 66 of the electrostatic protection circuit, internal circuit 69, and optical signal input portion 70 are configured on a semiconductor substrate Psub as shown in FIG. 9B. Specifically, on a P-type substrate Psub, photoelectric conversion element 70 is formed by a first high-concentration N-type region 70a and a first high-concentration P-type region 70b, first protection element 65 is formed by a second high-concentration N-type region 65a and a second high-concentration P-type region 65b in a low-concentration N-type region Nw, and second protection element 66 is formed by a third high-concentration N-type region 66a and a third high-concentration P-type region 66b. In this manner, various elements are formed on the semiconductor substrate to achieve a predetermined operation, whereas an element that has not originally been intended, what is called a parasitic element, is formed due to the configuration of the element.

In FIG. 9B, circuit designation shown with a solid line represents an intended element, while circuit designation shown with a dashed line represents a parasitic element. FIG. 9B shows that a parasitic NPN transistor PT is formed as a parasitic element, by first high-concentration N-type region 70a, first high-concentration P-type region 70b and third high-concentration N-type region 66a.

Here, an operation when a parasitic element is present and a voltage not smaller than the first positive overvoltage is applied to input terminal 61 will be described. If the voltage not smaller than the first positive overvoltage is applied to input terminal 61, the current that flows through first diode 65 is in the forward direction and the current flows through the path shown with I+. Therefore, as in the case of current path I+shown in the equivalent circuit diagram in FIG. 10A, internal circuit 69 is protected against the voltage not smaller than the first positive overvoltage.

Next, an operation when a voltage not larger than the first negative overvoltage is applied to the input terminal will be described. In this case, as the current that flows through second diode 66 is in the forward direction, the current flows through the path shown with I−. Here, as shown in the equivalent circuit diagram in FIG. 10B, the voltage not larger than the first negative overvoltage is not applied to internal circuit 69. On the other hand, in a state in which first high-concentration P-type region 70b serving as the base of parasitic transistor PT is fixed to reference voltage Vss, parasitic transistor PT is turned on, and an unnecessary current Ip flows from first high-concentration N-type region 70a to second high-concentration N-type region 66a. As current Ip is not distinguished from a signal generated when an optical signal is externally input, it is transmitted to internal circuit 69 as noise signal.

In particular, as the photodiode used as photoelectric conversion element 7 has an amplification factor higher than a normal diode, even an applied electrostatic noise signal is amplified. For example, if electrostatic noise is applied during reading of a portion that should be read as black (in which case the current does not flow through the photodiode), such image quality deterioration that pixel data of that portion is shown with white is caused. Though description has been given with regard to an input circuit, it is applicable to an example in which electrostatic noise is generated in the vicinity of output terminal 83.

In particular, in flatbed scanner 500 as shown in FIG. 7, as flexible cable 53 transmitting and receiving data and a wiring connected to the semiconductor chip arranged in the longitudinal direction are provided, electrical wiring from control unit 52 to the terminal of the semiconductor chip is as long as approximately 60 cm to 1 m. As such electrical wiring serves as a kind of antenna picking up electrostatic noise, flatbed scanner 500 has been used in an environment in which the semiconductor chip tends to receive the electrostatic noise. In general, measures such as mixing of a conductive substance in glass 54 through which the image is read or use of a shield with metal of the glass surface are available as methods for preventing the electrostatic noise, however, it has been difficult to employ such measures for preventing the electrostatic noise, because a component on or above optical signal input means should essentially be clear and colorless.

### SUMMARY OF THE INVENTION

An object of the present invention is to retain immunity to electrostatic breakdown and to prevent malfunction due to input of electrostatic noise to a parasitic element in a semiconductor device used for a photoelectric conversion device.

The present invention is directed to a semiconductor device including a photoelectric conversion element 7 outputting an electric signal in accordance with an externally input optical signal, an internal circuit 9 processing the electric signal, a signal terminal 1 inputting or outputting a signal to internal circuit 9, a first voltage terminal 2 supplying a first voltage, and a second voltage terminal 3 supplying a second voltage lower than the first voltage. The semiconductor device further includes a first protection element 4 connected in an electrically reverse direction between signal terminal 1 and the first voltage terminal and having at least one PN junction and a second protection element 5 connected in an electrically reverse direction between the first voltage terminal and the second voltage terminal and having at least one PN junction.

Desirably, in a semiconductor device 100, second protection element 5 is arranged between signal terminal 1 and first protection element 4 on one semiconductor substrate.

In the semiconductor device, desirably, photoelectric conversion element 7 and internal circuit 9 are arranged successively from one side of longitudinal sides of a semiconductor chip, and signal terminal 1, first protection element 4 and second protection element 5 provided closer to signal terminal 1 than first protection element 4 are arranged in the vicinity of the other side thereof.

Desirably, semiconductor device 100 has: a P-type semiconductor substrate Psub; photoelectric conversion element 7 formed by a first high-concentration N-type semiconductor region 7a connected to internal circuit 9 and a first high-concentration P-type semiconductor region 7b connected to the second voltage terminal, that are formed in P-type semiconductor substrate Psub; first protection element 4 formed by a low-concentration N-type semiconductor region Nw, a second high-concentration N-type semiconductor region 4a connected to first voltage terminal 2 formed in low-concentration N-type semiconductor region Nw, and a second high-concentration P-type semiconductor region 4b connected to signal terminal 1, that are formed in P-type semiconductor substrate Psub; second protection element 5 formed by a third high-concentration N-type semiconductor region 5a connected to the first voltage and a third high-concentration P-type semiconductor region 5b connected to the second voltage, that are provided on P-type substrate Psub adjacent to low-concentration N-type semiconductor region Nw; and internal circuit 9 processing the electric signal output from photoelectric conversion element 7 and an electric signal input from the signal terminal.

Desirably, in semiconductor device 100, third high-concentration N-type semiconductor region 5a connected to the first voltage terminal is arranged in the vicinity of signal terminal 1.

Desirably, in the semiconductor device, a resistance between second high-concentration N-type semiconductor region 4a and third high-concentration N-type semiconductor region 5a is set to a value from 0.1 m Ω to 100 Ω.

A second feature is directed to a semiconductor device 200 including a photoelectric conversion element 27 outputting an electric signal in accordance with an externally input optical signal, an internal circuit 29 processing the electric signal, a signal terminal 21 inputting or outputting a signal to internal circuit 29, a first voltage terminal 22 supplying a first voltage, and a second voltage terminal 23 supplying a second voltage lower than the first voltage. The semiconductor device further includes a first protection element 24 connected in an electrically reverse direction between signal terminal 21 and a second voltage and having at least one PN junction and a second protection element 25 connected in an electrically reverse direction between the first voltage terminal and the second voltage terminal and having at least one PN junction.

Desirably, in semiconductor device 200, second protection element 25 is arranged between signal terminal 21 and first protection element 24 on one semiconductor substrate.

In semiconductor device 200, photoelectric conversion element 27 and internal circuit 29 are arranged successively from one side of longitudinal sides of a semiconductor chip, and signal terminal 21, first protection element 24 and second protection element 25 provided closer to signal terminal 21 than the first protection element are arranged in the vicinity of the other side thereof.

Desirably, semiconductor device 200 has: an N-type semiconductor substrate Nsub; photoelectric conversion element 27 formed by a first high-concentration P-type semiconductor region 27b connected to internal circuit 29 and a first high-concentration N-type semiconductor region 27a connected to the first voltage, that are formed in N-type semiconductor substrate Nsub; first protection element 24 formed by a low-concentration P-type semiconductor region Pw, a second high-concentration P-type semiconductor region 24b connected to second voltage terminal 23 formed in low-concentration P-type substrate Pw, and a second high-concentration N-type semiconductor region 24a connected to signal terminal 21, that are formed in N-type semiconductor substrate Nsub; second protection element 25 formed by a third high-concentration N-type semiconductor region 25a connected to the first voltage terminal and a third high-concentration P-type semiconductor region 25b connected to the second voltage terminal, that are provided on N-type substrate Nsub adjacent to low-concentration P-type semiconductor region Pw; and internal circuit 29 processing the electric signal output from photoelectric conversion element 27 and an electric signal input from signal terminal 21.

Desirably, in semiconductor device 200, third high-concentration P-type semiconductor region 25b connected to the second voltage terminal is arranged in the vicinity of signal terminal 21.

Desirably, in semiconductor device 200, a resistance between second high-concentration P-type semiconductor region 24b and third high-concentration P-type semiconductor region 25b is set to a value from 0.1 m Ω to 100 Ω.

Desirably, in semiconductor devices 100 and 200, a frequency of the signal input to signal terminal 21 is set at least to 0.2 MHz.

In semiconductor chip 600a formed in a rectangular shape, M (M is an integer equal to or larger than 2) photoelectric conversion elements 7 of semiconductor device 100 may be arranged along a longitudinal direction of rectangle.

In a photoelectric conversion device formed in a rectangular shape such as an image sensor, N (N is an integer equal to or larger than 2) semiconductor chips 600a may be arranged for use along a longitudinal direction of rectangle.

The photoelectric conversion device using the semiconductor chip according to the subject application may be used as an image sensor portion of flatbed scanner 500, a sheet feed scanner 400, and a copying machine.

With the use of the semiconductor device according to the present invention, even if pulsed noise such as electrostatic noise is input to the semiconductor device, turn-on of the parasitic element can be suppressed by fixing a voltage of an impurity region implementing the parasitic element resulted from a vertical structure. Therefore, deterioration in an image such as generation of a lateral line across the image can be suppressed. In addition, without providing one of the diodes that have been connected in an electrically reverse direction to the power supply voltage side and the reference voltage side respectively of a conventional input/output terminal, immunity to electrostatic breakdown can be improved and breakdown of the internal circuit due to electrostatic noise can be suppressed by providing a diode connected in an electrically reverse direction between the reference voltage and the power supply voltage.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are circuit diagrams of a semiconductor device using a photoelectric conversion element according to the present invention.

FIGS. 2A and 2B illustrate a current path when an abnormal voltage is applied to the semiconductor device according to the present invention.

FIGS. 3A and 3B are circuit diagrams of a semiconductor device using a photoelectric conversion element according to a second embodiment of the present invention.

FIGS. 4A and 4B illustrate a current path when an abnormal voltage is applied to the semiconductor device according to the second embodiment of the present invention.

FIG. 5 is a schematic diagram of circuit arrangement in the semiconductor device according to the present invention.

FIG. 6 is a cross-sectional view of an input portion of a sheet feed scanner.

FIG. 7 is a schematic diagram of a flatbed scanner.

FIG. 8 is a schematic diagram of an image sensor portion of the flatbed scanner.

FIGS. 9A and 9B are circuit configuration diagrams of a semiconductor device using a conventional photoelectric conversion element.

FIGS. 10A and 10B illustrate a current path when an abnormal voltage is applied to the semiconductor device using the conventional photoelectric conversion element.

### DESCRIPTION OF THE PREFERRED EMBODIMENTS

In a semiconductor device incorporating a photoelectric conversion element and an electrostatic breakdown prevention circuit, immunity to electrostatic breakdown is improved and malfunction of the photoelectric conversion element due to electrostatic noise is prevented even when electrostatic noise is applied to its signal terminal.

### First Embodiment

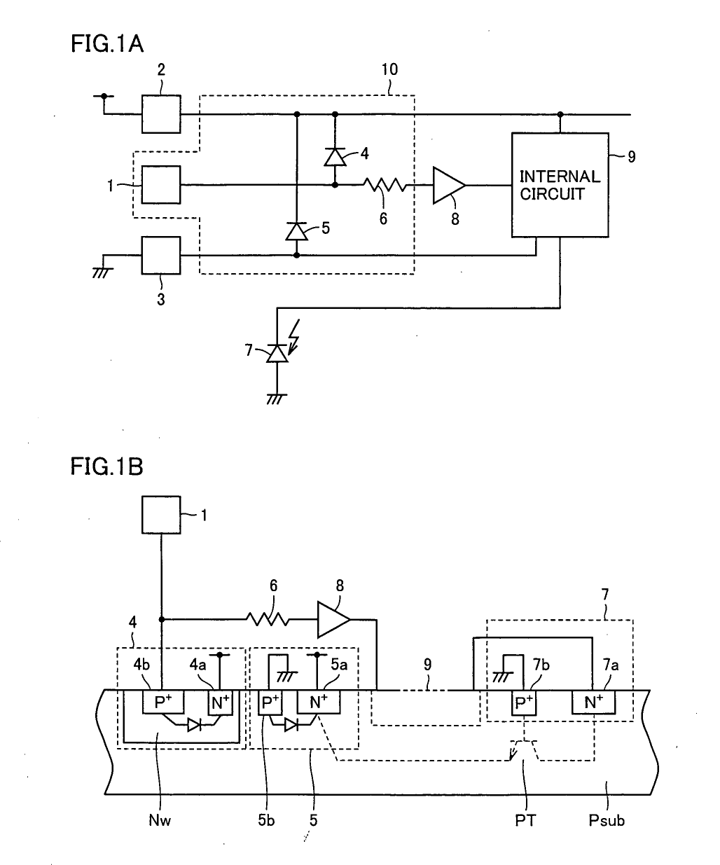

A configuration of a semiconductor device according to one embodiment of the present invention will be described with reference to FIG. 1A. Semiconductor device 100 according to the present invention includes as terminals, signal terminal 1 receiving a fluctuating electric signal, first voltage terminal 2 receiving, for example, first voltage Vcc as the power supply voltage, and second voltage terminal 3 receiving, for example, second voltage Vss lower than the first voltage as a ground voltage. An electrostatic protection circuit 10 is configured with first protection element 4 having the anode connected to signal terminal 1 and the cathode connected to the first voltage terminal (a diode is shown as an example of the protection element), second protection element 5 having the cathode side connected to the first voltage terminal and the anode side connected to second voltage terminal 3, and a resistor 6 having one end connected to a point of connection of signal terminal 1 and the anode of first protection element 4. In addition, the semiconductor device is configured with photoelectric conversion element 7 converting input light to the electric signal and internal circuit 9 receiving the electric signal output from photoelectric conversion element 7 and a signal input from signal terminal 1 through electrostatic protection circuit 10 and a first buffer 8 and operating and outputting the signals.

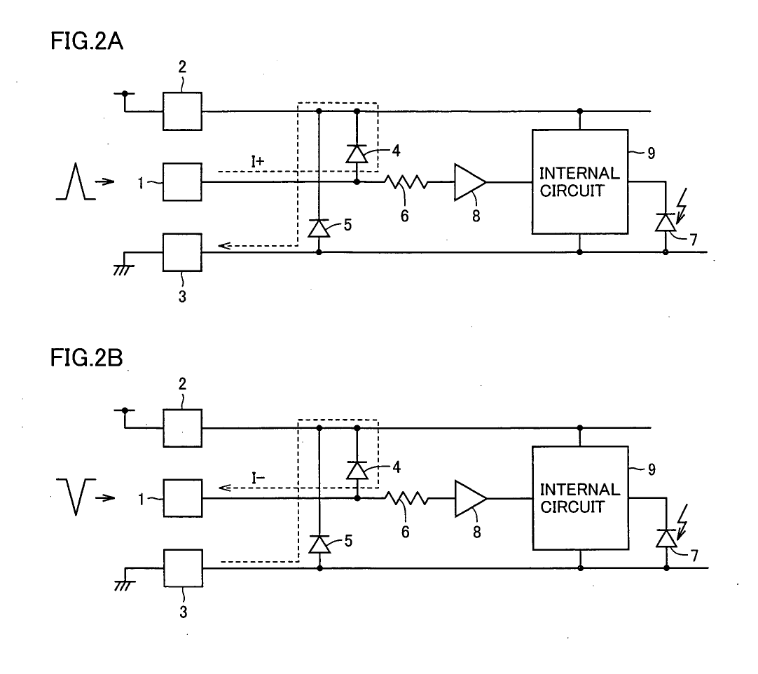

An example in which a voltage not smaller than a prescribed voltage (Vcc+Vf1+Vb2 (V), hereinafter referred to as a second positive overvoltage) is applied to signal terminal 1 will be described with reference to FIG. 2A. Here, the first voltage is denoted as power supply voltage Vcc, the second voltage is denoted as ground voltage Vss, the forward voltage of the first protection element is denoted as Vf1, a breakdown voltage thereof is denoted as Vb1, the forward voltage of the second protection element is denoted as Vf2, and a breakdown voltage thereof is denoted as Vb2. If the voltage not smaller than the second positive overvoltage is applied to signal terminal 1, the current flows through the path shown with I+, which is a forward direction with respect to first protection element 4 and a reverse direction with respect to second protection element 5. Therefore, the voltage not smaller than the second positive overvoltage is not applied to internal circuit 9.

An operation when a voltage not larger than a prescribed voltage (Vss−Vf2−Vb1 (V), hereinafter referred to as a second negative overvoltage) is applied to signal terminal 1 will be described with reference to FIG. 2B. If the voltage not larger than the second negative overvoltage is applied to signal terminal 1, the current flows through the path shown with I−, which is a forward direction with respect to second protection element 5 and a reverse direction with respect to first protection element 4. Therefore, the voltage not larger than the second negative overvoltage is not applied to internal circuit 9.

As shown in FIG. 1B, semiconductor device 100 is configured with: P-type semiconductor substrate Psub; internal circuit 9 formed on P-type semiconductor substrate Psub; photoelectric conversion element 7 formed by first high-concentration N-type semiconductor region 7a connected to internal circuit 9 and first high-concentration P-type semiconductor region 7b connected to the second voltage; first protection element 4 formed by second high-concentration N-type semiconductor region 4a connected to first voltage terminal 2 formed in low-concentration N-type semiconductor region Nw and second high-concentration P-type semiconductor region 4b connected to signal terminal 1, that are formed in P-type semiconductor substrate Psub; second protection element 5 formed by third high-concentration N-type semiconductor region 5a connected to the first voltage and third high-concentration P-type semiconductor region 5b connected to the second voltage, that are provided adjacent to low-concentration N-type semiconductor region Nw; and internal circuit 9 receiving the electric signal output from photoelectric conversion element 7 and the input signal input from the signal terminal and operating and outputting these signals.

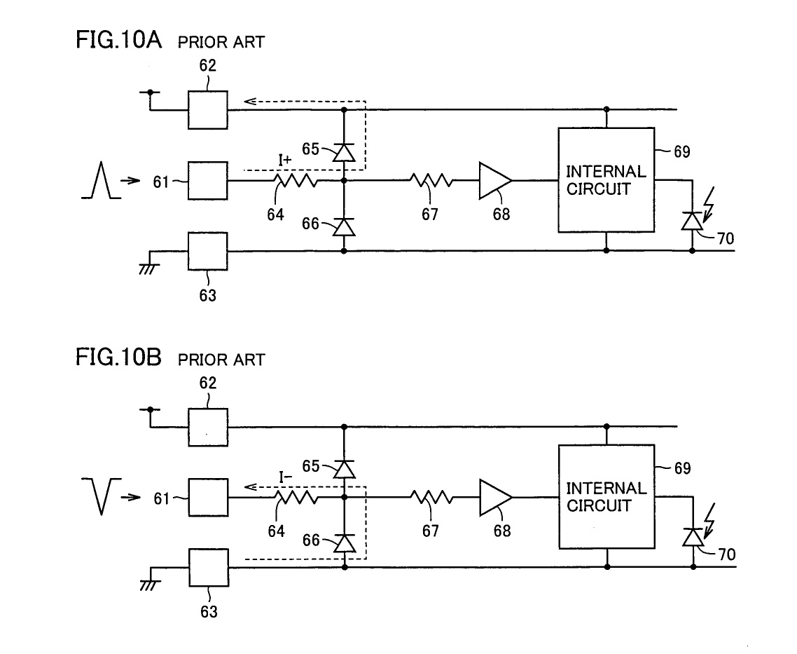

Here, an operation taking into consideration parasitic transistor PT serving as the parasitic element will be described with reference to FIG. 1B. Here, the first voltage is denoted as power supply voltage Vcc, the second voltage is denoted as ground voltage Vss, the forward voltage of the first protection element is denoted as Vf1, the breakdown voltage thereof is denoted as Vb1, the forward voltage of the second protection element is denoted as Vf2, and the breakdown voltage thereof is denoted as Vb2. If the voltage not smaller than the second positive overvoltage is applied to signal terminal 1, the current flows through the path shown with I+, which is the forward direction with respect to first protection element 4 and the reverse direction with respect to second protection element 5. Therefore, the voltage not smaller than the second positive overvoltage is not applied to internal circuit 9. Here, internal circuit 9 is protected against the voltage not smaller than the second positive overvoltage, as in the case of current path I+shown in the equivalent circuit diagram in FIG. 10A. In addition, turn-on of parasitic transistor PT due to electrostatic noise is suppressed.

An operation when a voltage not larger than the second negative overvoltage is applied to signal terminal 1 will be described. First high-concentration N-type region 7a serving as the collector of parasitic transistor PT is connected to the internal circuit, first high-concentration P-type region 7b serving as the base is fixed to second voltage Vss, and third high-concentration state 5a serving as the emitter is fixed to first voltage Vcc. Even if the voltage not larger than the second negative overvoltage is applied to signal terminal 1, the third high-concentration region N-type region that should serve as the emitter of parasitic transistor PT is fixed to first voltage Vcc. As the voltage of the third high-concentration N-type region is not lowered to first voltage Vcc or lower, parasitic transistor PT does not operate.

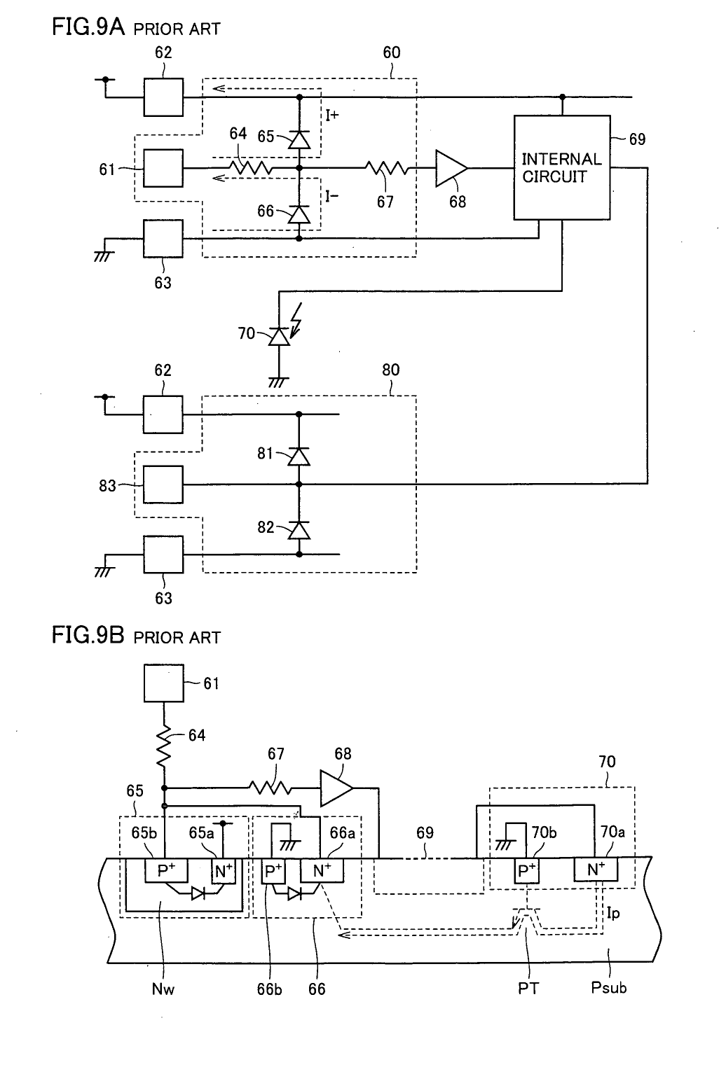

According to the conventional structure, as a result of turn-on of parasitic transistor PT shown in FIG. 9B, the unnecessary current flows and photoelectric conversion element 70 operates. According to the invention of the subject application, however, the current based on application of a negative abnormal voltage does not flow from first high-concentration N-type region 7a to first high-concentration P-type region 7b. Therefore, malfunction of photoelectric conversion element 70 due to the electrostatic noise signal as in the conventional example is suppressed. For example, such image quality deterioration that a portion of the image that should be read as black is shown with white is suppressed, and breakdown of internal circuit 9 due to the negative abnormal voltage can also be suppressed. Though description has been given with regard to the input circuit, it is applicable to an example in which similar electrostatic noise is generated in the vicinity of the output terminal.

### Second Embodiment

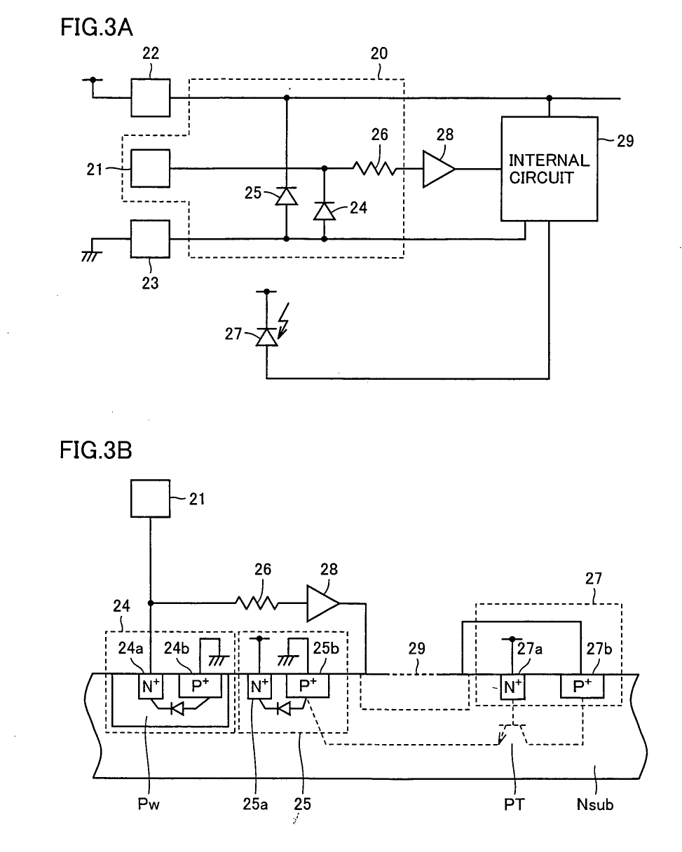

A configuration of semiconductor device 200 according to another embodiment of the present invention will be described with reference to FIG. 3A. Semiconductor device 200 according to the present invention includes as terminals, signal terminal 21 receiving a fluctuating electric signal, first voltage terminal 22 receiving, for example, first voltage Vcc as the power supply voltage, and second voltage terminal 23 receiving, for example, second voltage Vss lower than the first voltage as the ground voltage. An electrostatic protection circuit 20 is configured with first protection element 24 having the cathode connected to signal terminal 21 and the anode connected to second voltage terminal 23, second protection element 25 having the cathode side connected to first voltage terminal 22 and the anode side connected to second voltage terminal 23, and a resistor 26 having one end connected to a point of connection of signal terminal 21 and the cathode of first protection element 24. In addition, the semiconductor device is configured with photoelectric conversion element 27 converting input light to the electric signal and internal circuit 29 receiving the electric signal output from photoelectric conversion element 27 and a signal input from signal terminal 21 through electrostatic protection circuit 20 and a first buffer 28 and operating and outputting the signals.

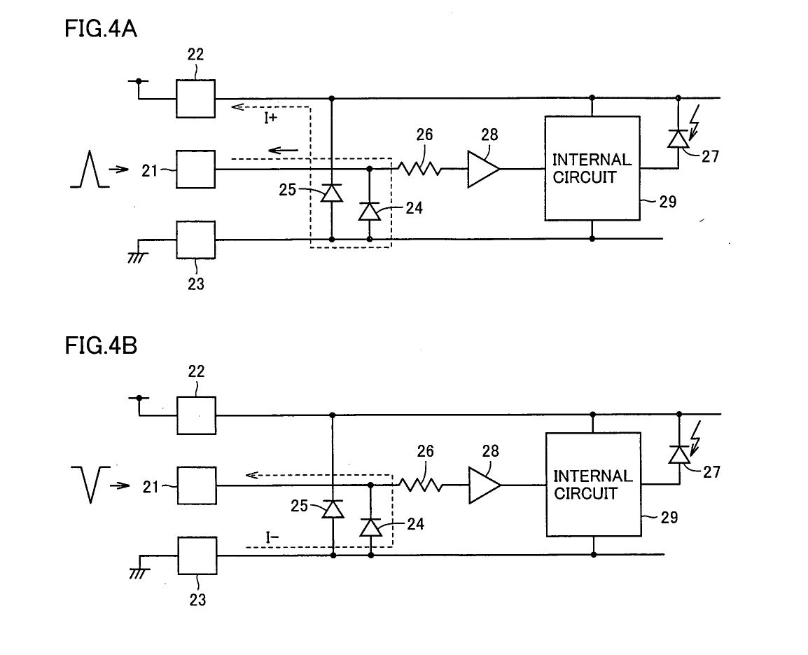

An example in which a voltage not smaller than a prescribed voltage (Vcc+Vf2+Vb1 (V), hereinafter referred to as a third positive overvoltage) is applied to signal terminal 21 will be described with reference to FIG. 4A. Here, the forward voltage of the first protection element is denoted as Vf1, the breakdown voltage thereof is denoted as Vb1, the forward voltage of the second protection element is denoted as Vf2, and the breakdown voltage thereof is denoted as Vb2. If the voltage not smaller than the third positive overvoltage is applied to signal terminal 21, the current flows through the path shown with I+, which is the reverse direction with respect to the first protection element and the forward direction with respect to the second protection element. Therefore, the voltage not smaller than the third positive overvoltage is not applied to internal circuit 29.

An operation when a voltage not larger than a prescribed voltage (Vss−Vf1 (V), hereinafter referred to as a third negative overvoltage) is applied to signal terminal 21 will be described with reference to FIG. 4B. If the voltage not larger than the third negative overvoltage is applied to signal terminal 21, the current flows through the path shown with I−, which is the forward direction with respect to the first protection element. Therefore, the voltage not larger than the third negative overvoltage is not applied to internal circuit 29.

As shown in FIG. 3B, semiconductor device 200 is configured with: N-type semiconductor substrate Nsub; photoelectric conversion element 27 formed by first high-concentration P-type semiconductor region 27b connected to internal circuit 29 and first high-concentration N-type semiconductor region 27a connected to the first voltage terminal, that are formed in N-type semiconductor substrate Nsub; first protection element 24 formed by second high-concentration P-type semiconductor region 24b connected to second voltage terminal 23 formed in low-concentration P-type semiconductor region Pw, and second high-concentration N-type semiconductor region 24a connected to signal terminal 21, that are formed in N-type semiconductor substrate Nsub; second protection element 25 formed by third high-concentration N-type semiconductor region 25a connected to the first voltage and third high-concentration P-type semiconductor region 25b connected to the second voltage, that are provided adjacent to low-concentration P-type semiconductor region Pw; and internal circuit 29 receiving the electric signal output from photoelectric conversion element 27 and the input signal input from the signal terminal and operating and outputting these signals.

Here, an operation taking into consideration parasitic transistor PT serving as the parasitic element will be described with reference to FIG. 3B. Here, an operation when the voltage not larger than the third negative overvoltage is applied to signal terminal 21 will be described. If the voltage not larger than the third negative overvoltage is applied to signal terminal 21, the current flows through the path shown with I−, which is the forward direction with respect to the first protection element. Therefore, the voltage not larger than the third negative overvoltage is not applied to internal circuit 29. In addition, turn-on of parasitic transistor PT due to electrostatic noise is suppressed.

An operation when a voltage not smaller than the third positive overvoltage is applied to signal terminal 21 will now be described. First high-concentration P-type region 27b serving as the collector of parasitic transistor PT is connected to internal circuit 29, first high-concentration N type region 27a serving as the base is fixed to first voltage Vcc, and third high-concentration P-type region 25b serving as the emitter is fixed to second voltage Vss. Even if a voltage not smaller than Vcc+Vf2+Vb1 (V) is applied to the signal terminal, parasitic transistor PT does not operate, because the third high-concentration region P-type region that should serve as the emitter of parasitic transistor PT is fixed to the second voltage. According to the conventional configuration, the unnecessary current due to the electrostatic noise flows and the parasitic transistor is turned on, however, the current based on application of the electrostatic noise does not flow from the first high-concentration N-type region to the first high-concentration P-type region.

Therefore, malfunction of photoelectric conversion element 27 due to the electrostatic noise signal as in the conventional example is suppressed. For example, such image quality deterioration that a portion of the image that should be read as black is shown with white is suppressed, and breakdown of internal circuit 29 due to the positive abnormal voltage can also be suppressed by providing the electrostatic protection circuit. Though description has been given with regard to the input circuit, it is applicable to an example in which similar electrostatic noise is generated in the vicinity of the output terminal.

A layout of the photoelectric conversion element and the electrostatic protection circuit of the subject application will be described with reference to FIG. 5. A photodiode serving as photoelectric conversion element 7 and internal circuit 9 are arranged successively from one side of the longitudinal sides of the chip, and pad 1 serving as the signal terminal, first protection element 4 and second protection element 5 provided closer to the pad relative to the first protection element are arranged in the vicinity of the other side thereof. A first voltage line VddL 32 receiving the first voltage is arranged on a side of the photoelectric conversion element adjacent to these protection elements and a second voltage line VssL 33 receiving the second voltage is arranged on opposite side.

In addition, the internal circuit includes an analog circuit portion 9a in the vicinity of the photodiode and a digital circuit portion 9b on a side of the pad and the like. Analog circuit portion 9a performs, for example, amplification and operation of the signal output from the photoelectric conversion element. The signal output from analog circuit portion 9a is converted to a digital signal by an analog-digital conversion portion (not shown). Digital circuit portion 9b processes and operates the digital signal output from the analog-digital conversion portion and a digital signal input from a signal terminal 1, and thereafter outputs the resultant signal to the outside of the chip through the output terminal.

As a result of application of the external electrostatic noise to signal terminal 1, parasitic transistor PT operates. Here, the parasitic element should be configured such that parasitic transistor PT implemented by photoelectric conversion element 7 and the high-concentration region connected to the pad does not operate.

For example, the high-concentration region supplied with a constant fixed voltage such as the power supply voltage or the reference voltage is arranged in the vicinity of signal terminal 1, so that parasitic transistor PT that has been configured with the PN junction of photoelectric conversion element 7 and the high-concentration region connected to the conventional input/output terminal is now configured with the PN junction of photoelectric conversion element 7 and the high-concentration region connected to the fixed voltage. Even if the abnormal voltage is applied to signal terminal 1, parasitic transistor PT configured with the high-concentration region forming the photoelectric conversion element and the high-concentration region receiving the fixed voltage does not turn on, because the high-concentration region in the vicinity of the signal terminal is set to the fixed voltage.

Alternatively, when the diode is configured with another high-concentration region having an electric characteristic opposite to the high-concentration region, turn-on of the parasitic transistor can be suppressed and breakdown of the internal circuit due to the abnormal voltage can be prevented.

Moreover, analog circuit portion 9a is desirably provided closer to photoelectric conversion element 7 relative to digital circuit portion 9b, in order to efficiently amplify the electric signal output from photoelectric conversion element 7 as well as to minimize influence of the noise signal due to a high-speed operation of digital circuit portion 9b onto photoelectric conversion element 7.

An example in which the P-type substrate is used will now be described. Desirably, a resistance between second high-concentration N-type region 4a and third high-concentration N-type region 5a is set to a value from 0.1 mΩ to 100Ω. When the resistance between second high-concentration N-type region 4a and third high-concentration N-type region 5a is set as above, current flow from first protection element 4 to second protection element 5 and vice versa is more likely and the present invention attains higher effect.

Higher effect can be obtained if the invention of the subject application is used as a clock terminal receiving a signal of high frequency among the input/output terminals. With regard to a signal such as a start signal or an enable signal of which transition is not observed until the function of the chip is stopped once the signal is input to the chip, a defect is less likely unless a voltage out of a prescribed range is input.

In contrast, with regard to a signal such as a clock signal that constantly operates during the operation of the chip, charges are accumulated in the vicinity of the high-concentration region of the input/output terminal that has conventionally served as the emitter of the parasitic transistor, in the event that overshoot or undershoot takes place frequently if not as serious as the abnormal voltage. In such a case, a phenomenon similar to that in application of the abnormal voltage occurs.

With the use of the semiconductor device as in the present invention, such a phenomenon as accumulation of charges in the region implementing the parasitic transistor does not occur, and hence a defect is less likely. If it is difficult to provide a second protection element in every terminal due to a chip size, it is desirable to employ the present invention for the clock terminal that constantly operates from turn-on to turn-off of the chip. Here, the frequency of the signal input to the clock terminal should be set at least to 0.2 MHz, and more preferably to 3 MHz to 20 MHz.

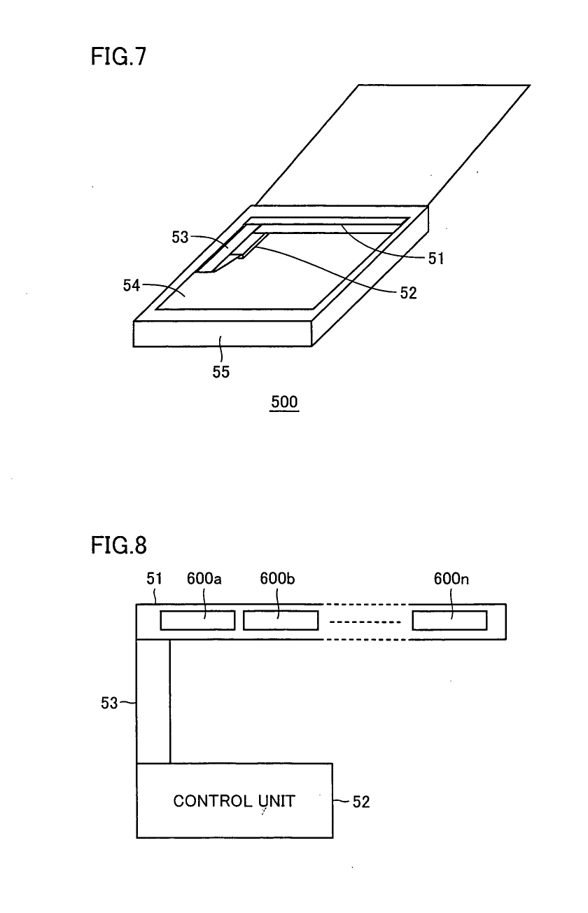

As semiconductor devices 100, 200 can suppress breakdown and malfunction due to static electricity, semiconductor devices 100, 200 can be used, for example, as image sensor portion 51 of flatbed scanner 500 and a copying machine such as a copier shown in FIG. 7.

As semiconductor devices 100, 200 can suppress breakdown and malfunction due to static electricity, semiconductor devices 100, 200 can be used as an image sensor arranged like an antenna susceptible to the electrostatic noise, that is, arranged longitudinally as shown in FIG. 8.

Though flatbed scanner 500 shown in FIG. 7 has exemplarily been described so far, the present invention is effective also in an input portion of sheet feed scanner 400 used as an image input apparatus in a communication apparatus such as a facsimile machine.

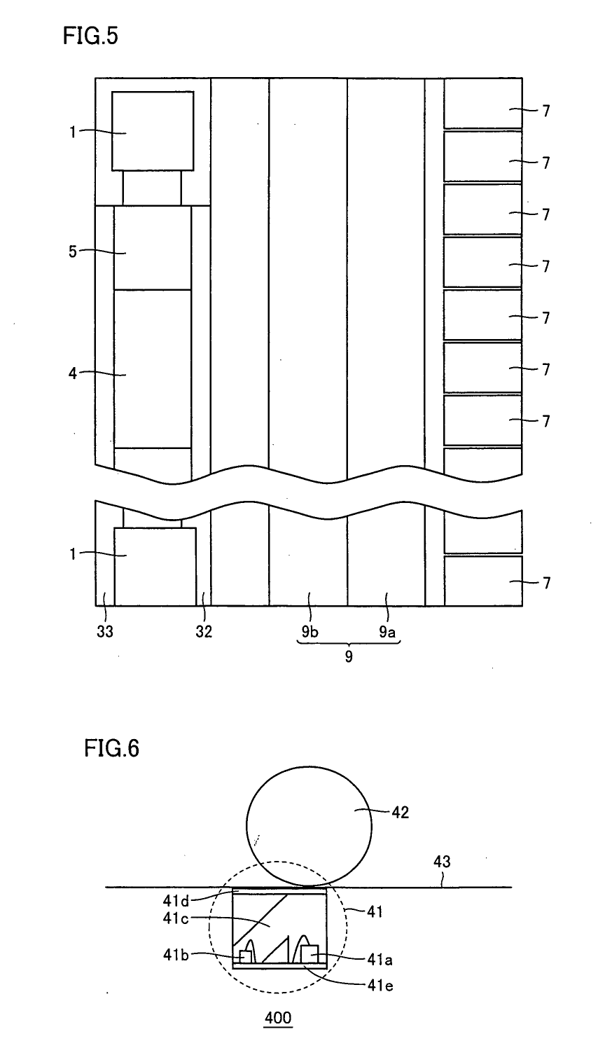

As shown in FIG. 6, sheet feed scanner 400 is constituted of an image sensor 41 and a platen 42 moving a document 43. The image sensor portion includes an input device 41a implemented by semiconductor device 100 or 200, a light source 41b irradiating the document with light, a light guiding portion 41c efficiently guiding the light emitted from the light source to the document, a glass portion 41d being in contact with document 43, and a substrate 41e carrying input device 41a and light source 41c.

In image sensor 41 of sheet feed scanner 400, in order to read document 43, document 43 is sandwiched between platen 42 and image sensor 51, and platen 42 is rotated so as to move document 43. At the same time, the document is irradiated with light by light source 41b through light guiding portion 41c and the light reflected from the surface of document 43 is input to input device 41a through a path different from that in irradiation.

Unlike image sensor 51 of flatbed scanner 500, as the image sensor portion is arranged inside a reading device, input of static electricity from the human body or the like is hardly likely. On the other hand, static electricity is generated by friction between image sensor 41, platen 42 and document 43, and charges are born in the vicinity thereof. Since light guiding portion 41c made of a transparent insulator is provided in the vicinity of input device 41 as in the case of flatbed scanner 500, it is impossible to dissipate the charges. Here, with the use of the input device employing semiconductor device 100 or 200 that exhibits high immunity to noise caused by the static electricity, the sheet feed scanner less likely to malfunction in spite of application of the electrostatic noise can be obtained.

Though the photodiode has been described as an example of the photoelectric conversion element, a CMOS phototransistor or the like may be employed. Namely, any element capable of photoelectric conversion and switching operation may be employed. Though the diode configuration has been described as an example of the first protection element and the second protection element, in configuring the diode, the diode may be formed as it is, or for example a MOS transistor or a bipolar transistor may be used. In addition, a single protection element or a plurality of protection elements in parallel may be provided, if permitted in terms of the chip size.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a photoelectric conversion element outputting an electric signal in accordance with an externally input optical signal;
an internal circuit receiving said electric signal;
a signal terminal inputting or outputting a signal to said internal circuit;
a first voltage terminal supplying a first voltage;
a second voltage terminal supplying a second voltage lower than the first voltage;
a first protection element connected in an electrically reverse direction between said signal terminal and said first voltage terminal and having at least one PN junction; and
a second protection element connected in an electrically reverse direction between said first voltage terminal and said second voltage terminal and having at least one PN junction.

2. The semiconductor device according to claim 1, wherein
said second protection element is arranged between said signal terminal and said first protection element on one semiconductor substrate.

3. The semiconductor device according to claim 1, wherein
said photoelectric conversion element and said internal circuit are arranged successively from one side of longitudinal sides of a semiconductor chip formed in a rectangular shape,
said signal terminal, said first protection element and said second protection element are provided in vicinity of another side of said longitudinal sides of the semiconductor chip, and
said second protection element is provided closer to said signal terminal than said first protection element.

4. The semiconductor device according to claim 1, further comprising a P-type semiconductor substrate; wherein
said photoelectric conversion element is formed by a first high-concentration N-type semiconductor region connected to said internal circuit and a first high-concentration P-type semiconductor region connected to the second voltage terminal, that are formed in said P-type semiconductor substrate,
said first protection element is formed by a low-concentration N-type semiconductor region, a second high-concentration N-type semiconductor region connected to the first voltage terminal formed in said low-concentration N-type semiconductor region, and a second high-concentration P-type semiconductor region connected to said signal terminal, that are formed in said P-type semiconductor substrate,
said second protection element is formed by a third high-concentration N-type semiconductor region connected to the first voltage terminal and a third high-concentration P-type semiconductor region connected to the second voltage terminal, that are provided on said P-type substrate adjacent to said low-concentration N-type semiconductor region, and
said internal circuit receives the electric signal output from said photoelectric conversion element and an electric signal input from said signal terminal.

5. The semiconductor device according to claim 4, wherein
said third high-concentration N-type semiconductor region connected to the first voltage terminal is arranged in vicinity of said signal terminal.

6. The semiconductor device according to claim 5, wherein
a wiring resistance between said second high-concentration N-type semiconductor region and said third high-concentration N-type semiconductor region is set to a value from 0.1 m Ω to 100 Ω.

7. A semiconductor device, comprising:
a photoelectric conversion element outputting an electric signal in accordance with an externally input optical signal;
an internal circuit receiving said electric signal;
a signal terminal inputting or outputting a signal to said internal circuit;
a first voltage terminal supplying a first voltage;
a second voltage terminal supplying a second voltage lower than the first voltage;
a first protection element connected in an electrically reverse direction between said signal terminal and said second voltage terminal and having at least one PN junction; and
a second protection element connected in an electrically reverse direction between said first voltage terminal and said second voltage terminal and having at least one PN junction.

8. The semiconductor device according to claim 7, wherein
said second protection element is arranged between said signal terminal and said first protection element on one semiconductor substrate.

9. The semiconductor device according to claim 7, wherein
said photoelectric conversion element and said internal circuit are arranged successively from one side of longitudinal sides of a semiconductor chip formed in a rectangular shape,
said signal terminal, said first protection element and said second protection element are arranged in vicinity of another side of said longitudinal sides of the semiconductor chip, and
said second protection element is provided closer to said signal terminal than said first protection element.

10. The semiconductor device according to claim 7, further comprising an N-type semiconductor substrate; wherein
said photoelectric conversion element is formed by a first high-concentration P-type semiconductor region connected to said internal circuit and a first high-concentration N-type semiconductor region connected to the first voltage terminal, that are formed in said N-type semiconductor substrate,
said first protection element is formed by a low-concentration P-type semiconductor region, a second high-concentration P-type semiconductor region connected to the second voltage terminal formed in said low-concentration P-type semiconductor region, and a second high-concentration N-type semiconductor region connected to said signal terminal, that are formed in said N-type semiconductor substrate,
said second protection element is formed by a third high-concentration N-type semiconductor region connected to the first voltage terminal and a third high-concentration P-type semiconductor region connected to the second voltage terminal, that are provided on said N-type substrate adjacent to said low-concentration P-type semiconductor region, and
said internal circuit receives the electric signal output from said photoelectric conversion element and an electric signal input from said signal terminal.

11. The semiconductor device according to claim 10, wherein
said third high-concentration P-type semiconductor region connected to a second voltage is arranged in vicinity of said signal terminal.

12. The semiconductor device according to claim 11, wherein
a wiring resistance between said second high-concentration P-type semiconductor region and said third high-concentration P-type semiconductor region is set to a value from 0.1 m Ω to 100 Ω.

13. The semiconductor device according to claim 1, wherein
the signal applied to said signal terminal has a frequency set at least to 0.2 MHz.

14. The semiconductor device according to claim 7, wherein
the signal applied to said signal terminal has a frequency set at least to 0.2 MHz.

15. The semiconductor device according to claim 1, wherein
in a semiconductor chip formed in a rectangular shape, M (M is an integer equal to or larger than 2) photoelectric conversion elements of said semiconductor device are arranged along a longitudinal direction of rectangle.

16. The semiconductor device according to claim 7, wherein
in a semiconductor chip formed in a rectangular shape, M (M is an integer equal to or larger than 2) photoelectric conversion elements of said semiconductor device are arranged along a longitudinal direction of rectangle.

17. A photoelectric conversion device formed in a rectangular shape comprising N (N is an integer equal to or larger than 2) semiconductor chips arranged along a longitudinal direction of rectangle; wherein
each said semiconductor chip includes
a photoelectric conversion element outputting an electric signal in accordance with an externally input optical signal,
an internal circuit receiving said electric signal,
a signal terminal inputting or outputting a signal to said internal circuit,
a first voltage terminal supplying a first voltage,
a second voltage terminal supplying a second voltage lower than the first voltage,
a first protection element connected in an electrically reverse direction between said signal terminal and said first voltage terminal and having at least one PN junction, and
a second protection element connected in an electrically reverse direction between said first voltage terminal and said second voltage terminal and having at least one PN junction.

18. A photoelectric conversion device formed in a rectangular shape comprising N (N is an integer equal to or larger than 2) semiconductor chips arranged along a longitudinal direction of rectangle; wherein
each said semiconductor chip includes
a photoelectric conversion element outputting an electric signal in accordance with an externally input optical signal,
an internal circuit receiving said electric signal,
a signal terminal inputting or outputting a signal to said internal circuit,
a first voltage terminal supplying a first voltage,
a second voltage terminal supplying a second voltage lower than the first voltage,
a first protection element connected in an electrically reverse direction between said signal terminal and said second voltage terminal and having at least one PN junction, and
a second protection element connected in an electrically reverse direction between said first voltage terminal and said second voltage terminal and having at least one PN junction.

19. A scanner comprising an image sensor portion; wherein
said image sensor portion includes a photoelectric conversion device formed in a rectangular shape,
said photoelectric conversion device includes N (N is an integer equal to or larger than 2) semiconductor chips arranged along a longitudinal direction of rectangle, and
each said semiconductor chip includes
a photoelectric conversion element outputting an electric signal in accordance with an externally input optical signal,
an internal circuit receiving said electric signal,
a signal terminal inputting or outputting a signal to said internal circuit,
a first voltage terminal supplying a first voltage,
a second voltage terminal supplying a second voltage lower than the first voltage,
a first protection element connected in an electrically reverse direction between said signal terminal and said first voltage terminal and having at least one PN junction, and
a second protection element connected in an electrically reverse direction between said first voltage terminal and said second voltage terminal and having at least one PN junction.

20. A scanner comprising an image sensor portion; wherein
said image sensor portion includes a photoelectric conversion device formed in a rectangular shape,
said photoelectric conversion device includes N (N is an integer equal to or larger than 2) semiconductor chips arranged along a longitudinal direction of rectangle, and
each said semiconductor chip includes
a photoelectric conversion element outputting an electric signal in accordance with an externally input optical signal,
an internal circuit receiving said electric signal,
a signal terminal inputting or outputting a signal to said internal circuit,
a first voltage terminal supplying a first voltage,
a second voltage terminal supplying a second voltage lower than the first voltage,
a first protection element connected in an electrically reverse direction between said signal terminal and said second voltage terminal and having at least one PN junction, and
a second protection element connected in an electrically reverse direction between said first voltage terminal and said second voltage terminal and having at least one PN junction.
